(19) United States
(12) Patent Application Publication
(10) Pub. No.: US 2009/0311844 A1
(43) Pub. Date: Dec. 17, 2009

(54) ALIGNMENT MARK AND METHOD FOR FABRICATING THE SAME AND ALIGNMENT METHOD OF SEMICONDUCTOR

(75) Inventors: Hung-Ming Lin, Hsinchu County (TW); Hsiao-Chiang Lin, Taipei County (TW); Meng-Feng Tsai, Taipei County (TW); De-An Chiu, Taoyuan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: POWERCHIP SEMICONDUCTOR CORP., Hsinchu (TW)

(21) Appl. No.: 12/140,285

(22) Filed: Jun. 17, 2008

(51) Int. Cl. H01L 21/76

(52) U.S. Cl. 438/401; 257/E23.179

(57) ABSTRACT

An alignment mark, disposed on a substrate, is provided. The alignment mark includes a first dielectric layer and a metal layer. The first dielectric layer is disposed on the substrate and includes an alignment trench and a contact hole. The metal layer is disposed in the alignment trench and the contact hole, wherein a surface of the metal layer is even with a surface of the first dielectric layer. Because the metal layer and the first dielectric layer have different reflection indexes and different refraction indexes, an alignment light detects the alignment mark according to these differences.

### BACKGROUND OF THE INVENTION

1. Field of the Invention

The present invention relates to a semiconductor element and a fabricating method thereof, and particularly relates to an alignment mark, a method for fabricating the same, and an alignment method of a semiconductor.

2. Description of Related Art

Photolithography, a critical process in the fabrication of semiconductor elements, has undoubted importance in the semiconductor process. Generally, it takes about 10 to 18 times of photolithography and exposure processes to complete the fabrication of an element, depending on its complexity. During the fabrication of semiconductors, the chip and the photomask need to be accurately aligned before each exposure so as to precisely transfer the pattern of the photomask onto the chip. Otherwise, the chip will be wasted.

A general method for aligning the chip is to form a plurality of trenches in a specific area of the wafer so as to define an alignment mark area. In each exposure process, the height difference between the surfaces of the trenches and the surface of the wafer is a characteristic of an alignment mark (also known as step height), and the optical path difference in light reflecting between the surfaces of the trenches and the surface of the wafer is used to detect the alignment mark to complete the alignment. Hence, the step height of the alignment mark needs to be above a minimum value, such as above 200 angstroms, so as to provide a distinct alignment signal.

However, as the deposition of material layers increases, the alignment mark is gradually covered by the layers deposited on the alignment mark area of the chip. As a consequence, the step height and the profile of the alignment mark become unobvious. Thereby, diffraction caused by the alignment mark is reduced. The reduction of diffraction would result in a feeble alignment signal or a much higher noise ratio, which causes the alignment sensor to fail to detect a proper alignment signal. Consequently, misalignment and improper pattern transfer occur. As a result, the reliability of the semiconductor element is greatly reduced, and the whole chip may be wasted.

### SUMMARY OF THE INVENTION

The present invention provides a method for forming an alignment mark which has a metal layer and a dielectric layer with different reflection indexes and refraction indexes, and thereby an alignment light detects the alignment mark.

The present invention provides an alignment mark which has a metal layer and a dielectric layer with different reflection indexes and refraction indexes for an alignment light to detect.

The present invention provides an alignment method for a semiconductor fabricating process, which increases the precision of pattern transfer by using an alignment mark having a metal layer and a dielectric layer with different reflection indexes and refraction indexes.

The present invention provides a method for forming an alignment mark. First, a substrate is provided. Then, a first dielectric layer comprising an alignment trench and a contact hole is formed on the substrate. A metal layer is formed on the substrate to fill the alignment trench and the contact hole. Thereafter, the metal layer outside the alignment trench and the contact hole is removed, wherein a surface of the metal layer in the alignment trench is even with a surface of the first dielectric layer, and the metal layer and the first dielectric layer have different reflection indexes and refraction indexes, by which the alignment light detects the alignment mark.

The present invention provides an alignment mark, which is disposed on a substrate and comprises a first dielectric layer and a metal layer. The first dielectric layer is disposed on the substrate and comprises an alignment trench and a contact hole. The metal layer is disposed in the alignment trench and the contact hole, wherein a surface of the metal layer is even with a surface of the first dielectric layer, and the metal layer and the first dielectric layer have different reflection indexes and refraction indexes, by which an alignment light detects the alignment mark.

The present invention provides an alignment method for a semiconductor fabricating process. First, a plurality of alignment marks and a plurality of conductive lines are formed in a first dielectric layer on the substrate. This process comprises forming a plurality of alignment trenches and a plurality of contact holes in the first dielectric layer first. A metal layer is then formed on the substrate to fill the alignment trenches and the contact holes. Thereafter, the metal layer outside the alignment trenches and the contact holes is removed, wherein a surface of the metal layer in the alignment trenches is even with a surface of the first dielectric layer. Next, a second dielectric layer is formed on the first dielectric layer. A mask layer is formed on the second dielectric layer. Following that, a photoresist layer is formed on the mask layer, and the alignment marks is detected by an alignment light so as to precisely transfer a pattern of a photomask onto the photoresist layer, wherein the alignment light detects the alignment marks according to the different reflection indexes and refraction indexes of the metal layer and the first dielectric layer.

In an embodiment of the present invention, the method for removing the metal layer outside the alignment trench and the contact hole comprises chemical mechanical polishing.

In an embodiment of the present invention, a width of the alignment trench is less than 0.75 micrometer.

In an embodiment of the present invention, a material of the first dielectric layer comprises silicon oxide.

In an embodiment of the present invention, the metal layer comprises tungsten.

In an embodiment of the present invention, a thickness of the metal layer is larger than 400 nanometers.

In an embodiment of the present invention, a material of the mask layer comprises amorphous carbon.

The alignment mark of the present invention has the metal layer and the dielectric layer with different reflection indexes and refraction indexes, and the alignment light detects the alignment mark according to these differences. Hence, the conventional problem that the alignment mark becomes unobvious as the material layers stacked thereon increase can be solved to achieve great precision. Moreover, the precision of pattern transfer can be increased by using the alignment mark of the present invention so as to improve the reliability of the element.

To make aforementioned features and advantages of the present invention more comprehensible, several embodiments accompanied with figures are described in detail as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A through FIG. 1D are cross-sectional views illustrating a process flow for fabricating a semiconductor element comprising an alignment mark according to an embodiment of the present invention.

FIG. 2 is a diagram illustrating an alignment method for a semiconductor fabricating process according to an embodiment of the present invention.

### DESCRIPTION OF EMBODIMENTS

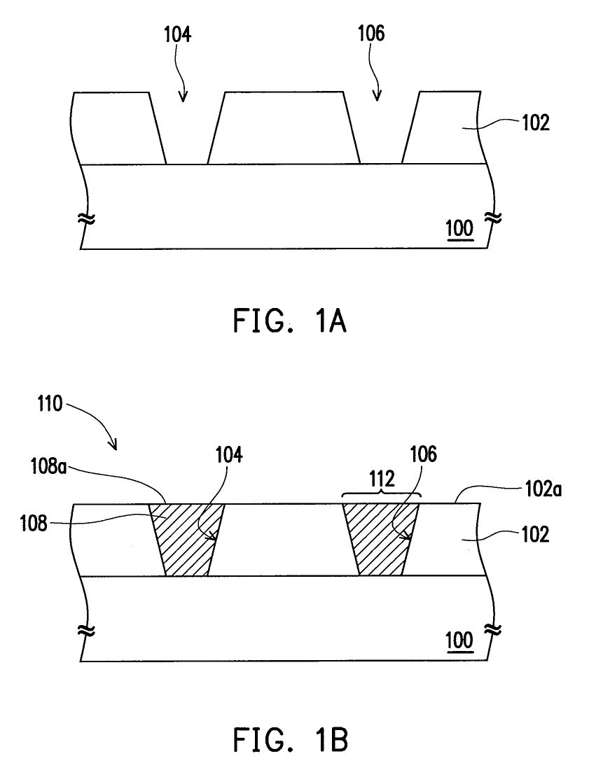

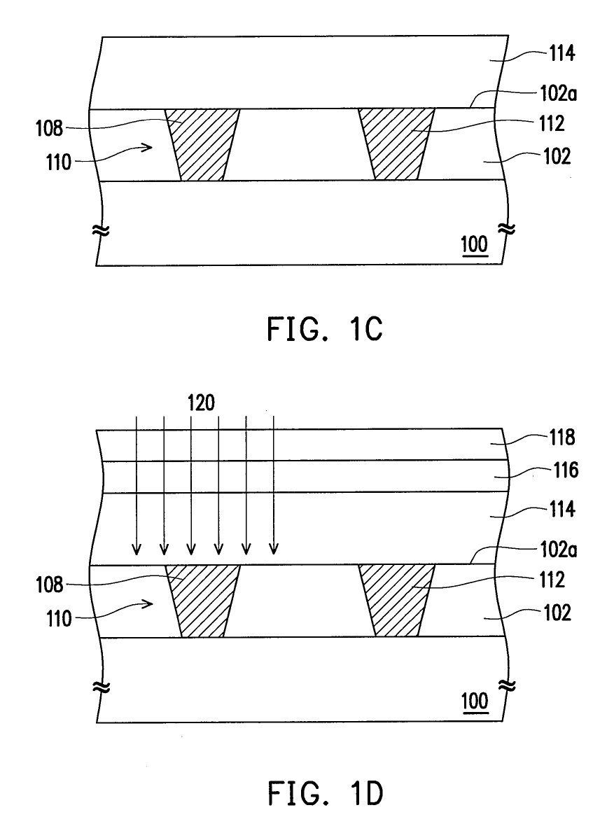

FIG. 1A through FIG. 1D are cross-sectional views illustrating a process flow for fabricating a semiconductor element comprising an alignment mark according to an embodiment of the present invention.

Referring to FIG. 1A, a substrate 100 is first provided. The substrate 100 is, for example, a silicon substrate. Then, a first dielectric layer 102 is formed on the substrate 100. A material of the first dielectric layer 102 is, for example, silicon oxide or other suitable dielectric materials. A method for forming the first dielectric layer 102 is, for example, chemical vapor deposition. Next, an alignment trench 104 and a contact hole 106 are formed in the first dielectric layer 102. It is noted that the alignment trench 104 is, for example, formed near a scribe line (not shown) in a wafer (not shown). A method for forming the alignment trench 104 and the contact hole 106 is, for example, to form a mask layer (not shown) on the first dielectric layer 102. Then a photolithography process and an etching process are performed to remove a portion of the mask layer. Thereafter, the remaining mask layer is used as an etching mask to etch the first dielectric layer 102. It is noted that a width of the alignment trench 104 in this embodiment is less than 0.75 micrometer, which is smaller than a width of a conventional alignment trench.

Referring to FIG. 1B, a metal layer 108 is then formed on the substrate 100 to fill the alignment trench 104 and the contact hole 106. A material of the metal layer 108 is, for example, tungsten, and a method for forming the metal layer 108 is, for example, chemical vapor deposition. It is noted that the alignment trench 104 has to be filled up with the metal layer 108. In this embodiment, a thickness of the metal layer 108 is, for example, larger than 400 nanometers. Then, the metal layer 108 outside the alignment trench 104 and the contact hole 106 is removed so that a surface 108a of the metal layer 108 in the alignment trench 104 is even with a surface 102a of the first dielectric layer 102. Thereby, an alignment mark 110 and a conductive line 112 are formed. Herein, a method for removing the metal layer 108 outside the alignment trench 104 and the contact hole 106 is, for example, to perform chemical mechanical polishing by using the first dielectric layer 102 as a polishing stop layer. In other words, the metal layer 108 in the alignment trench 104 has a flat surface 108a. Moreover, the metal layer 108 and the first dielectric layer 102 in the alignment mark 110 have different reflection indexes and refraction indexes, and an alignment light detects the alignment mark 110 according to these differences. Hence, the alignment mark 110 retains characteristics for an alignment sensor (not shown) to detect even the material layers sequentially stacking thereon in the following processes.

Next, referring to FIG. 1C, a second dielectric layer 114 is formed on the first dielectric layer 102. A material of the second dielectric layer 114 is, for example, silicon nitride, and a method for forming the second dielectric layer 114 is, for example, chemical vapor deposition. Certainly, the second dielectric layer 114 may be formed by other light-transmittable materials, wherein the light is an alignment light for performing alignment. It is noted that, although the second dielectric layer 114 illustrated in the figure is a single layer, the second dielectric layer 114 may comprise a plurality of layers depending on the process. Moreover, the second dielectric layer 114 may serve as an inter-layer dielectric layer or an inter-metal dielectric layer in a semiconductor element.

Referring to FIG. 1D, a mask layer 116 is then formed on the second dielectric layer 114. In this embodiment, a material of the mask layer 116 is, for example, amorphous carbon, and a method for forming the mask layer 116 is, for example, chemical vapor deposition. It is noted that the mask layer 116 is light-transmittable, wherein the light is an alignment light for performing alignment. Thereafter, a photoresist layer 118 is formed on the mask layer 116. A material of the photoresist layer 118 is, for example, a photosensitive material comprising resin, photosensitive agent, and solvent. A method for forming the photoresist layer 118 is, for example, a spin coating process. Next, a photomask (not shown) is provided. An alignment light 120 is used to detect the alignment mark 110 so as to align the photomask with the photoresist layer 118. Following that, an exposure process and a development process are performed on the photoresist layer 118 to transfer a pattern of the photomask onto the photoresist layer 118. The fabricating processes following the aforementioned pattern transfer process are known to persons of ordinary knowledge in this art, and therefore omitted hereafter. It is noted that the alignment light 120 detects the alignment mark 110 by the differences in the reflection indexes and the refraction indexes between the metal layer 108 and the first dielectric layer 102.

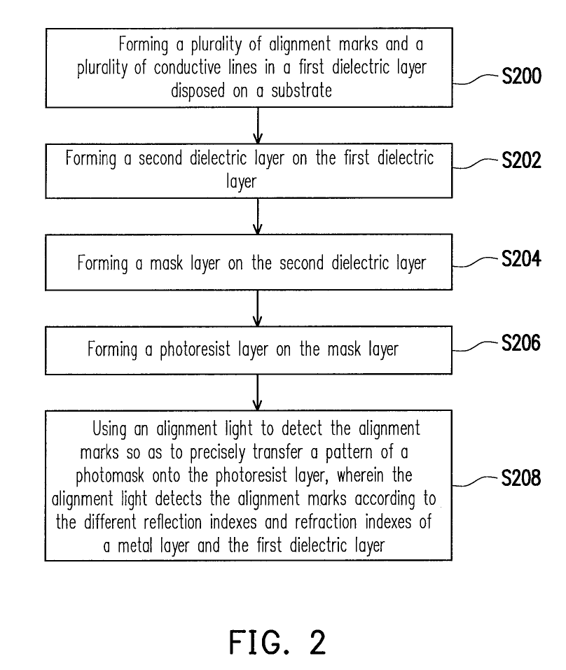

An alignment method of using the alignment mark 110 is detailed as follows. FIG. 2 is a diagram illustrating an alignment method for a semiconductor fabricating process according to an embodiment of the present invention.

Referring to FIG. 1B and FIG. 2, an alignment mark 110 and a conductive line 112 are illustrated in this embodiment. First, in a process S200, a plurality of alignment marks 110 and a plurality of conductive lines 112 are formed in the first dielectric layer 102 on the substrate 100. Please refer to the previous paragraphs for the forming methods of the alignment marks 110 and the conductive lines 112.

Referring to FIG. 1C and FIG. 2, a process S202 is then performed, and a second dielectric layer 114 is formed on the first dielectric layer 102. Please refer to the previous paragraphs for the forming method and material of the second dielectric layer 114. It is noted that, although the second dielectric layer 114 illustrated in the figure is a single layer, the second dielectric layer 114 is formed by stacking a plurality of layers in reality. In other words, the second dielectric layer 114 may comprise a plurality of dielectric layers if required.

Referring to FIG. 1D and FIG. 2, in a process S204, a mask layer 116 is formed on the second dielectric layer 114. Please refer to the previous paragraphs for the forming method and material of the mask layer 116. It is noted that, although the mask layer 116 illustrated in the figure is a single layer, the mask layer 116 may be a multiple layer comprising a plurality of mask material layers. In other words, the mask layer 116 may comprise a plurality of mask layers if required.

Referring to FIG. 1D and FIG. 2, a process S206 is then performed, and a photoresist layer 118 is formed on the mask layer 116. A material of the photoresist layer 118 is, for example, a photosensitive material comprising resin, photosensitive agent, and solvent. A method for forming the photoresist layer 118 is, for example, a spin coating process.

Thereafter, please refer to FIG. 1D and FIG. 2. In a process S208, an alignment light 120 is used to detect the alignment marks 110 so as to precisely transfer a pattern of a photomask (not shown) onto the photoresist layer 118, wherein the alignment light 120 detects the alignment marks 110 according to the different reflection indexes and refraction indexes of the metal layer 108 and the first dielectric layer 102. To be more specific, the alignment light 120 passes through the mask layer 114 and the second dielectric layer 116, and reaches the surface 102a of the first dielectric layer 102. According to the reflection differences of the first dielectric layer 102 and the metal layer 108, an alignment sensor (not shown) detects the alignment mark 110 to align the photomask with the photoresist layer 118 so as to precisely transfer a pattern of the photomask onto the photoresist layer 118. It is noted that, because the alignment light 120 detects the alignment mark 110 according to the different reflection indexes and refraction indexes of the first dielectric layer 102 and the metal layer 108, the conventional problem that the profile of the alignment mark becomes unobvious as the material layers stacked thereon increase can be solved. In addition, because the pattern of the photomask can be precisely transferred to the photoresist layer and the pattern can be formed in an accurate position on the substrate, the reliability of the semiconductor element is increased.

In summary, the alignment mark of the present invention has the metal layer and the dielectric layer with different reflection indexes and refraction indexes, and the alignment light detects the alignment mark according to these differences. Therefore, the conventional problem that the alignment mark becomes unobvious as the material layers stacked thereon increase can be overcome to achieve great precision. Consequently, the reliability of semiconductor elements is increased by using the alignment mark of the present invention. Moreover, the alignment method of the present invention can be integrated into an existing semiconductor fabricating process without greatly increasing production cost.

Although the present invention has been disclosed by the above embodiments, they are not intended to limit the present invention. Anybody skilled in the art may make some modifications and alterations without departing from the spirit and scope of the present invention. Therefore, the protecting range of the present invention falls in the appended claims.

What is claimed is:

1. A method for forming an alignment mark, comprising:
providing a substrate;
forming a first dielectric layer, having an alignment trench and a contact hole, on the substrate;
forming a metal layer on the substrate to fill the alignment trench and the contact hole; and
removing the metal layer outside the alignment trench and the contact hole, wherein a surface of the metal layer in the alignment trench is even with a surface of the first dielectric layer, and the metal layer and the first dielectric layer have different reflection indexes and refraction indexes, by which an alignment light detects the alignment mark.

2. The method of claim 1, wherein a method for removing the metal layer outside the alignment trench and the contact hole comprises chemical mechanical polishing.

3. The method of claim 1, wherein a width of the alignment trench is less than 0.75 micrometer.

4. The method of claim 1, wherein a material of the first dielectric layer comprises silicon oxide.

5. The method of claim 1, wherein a material of the metal layer comprises tungsten.

6. The method of claim 1, wherein a thickness of the metal layer is larger than 400 nanometers.

7. An alignment mark, disposed on a substrate, comprising:
a first dielectric layer disposed on the substrate, comprising an alignment trench and a contact hole; and
a metal layer disposed in the alignment trench and the contact hole, wherein a surface of the metal layer is even with a surface of the first dielectric layer, and the metal layer and the first dielectric layer have different reflection indexes and refraction indexes, by which an alignment light detects the alignment mark.

8. The alignment mark of claim 7, wherein a width of the alignment trench is less than 0.75 micrometer.

9. The alignment mark of claim 7, wherein a material of the first dielectric layer comprises silicon oxide.

10. The alignment mark of claim 7, wherein a material of the metal layer comprises tungsten.

11. The alignment mark of claim 7, wherein a thickness of the metal layer is larger than 400 nanometers.

12. An alignment method for a semiconductor fabricating process, comprising:
forming a plurality of alignment marks and a plurality of conductive lines in a first dielectric layer disposed on a substrate, comprising:
forming a plurality of alignment trenches and a plurality of contact holes in the first dielectric layer;
forming a metal layer on the substrate to fill the alignment trenches and the contact holes; and
removing the metal layer outside the alignment trenches and the contact holes, wherein a surface of the metal layer in the alignment trenches is even with a surface of the first dielectric layer;
forming a second dielectric layer on the first dielectric layer;
forming a mask layer on the second dielectric layer;
forming a photoresist layer on the mask layer; and
using an alignment light to detect the alignment marks so as to precisely transfer a pattern of a photomask onto the photoresist layer, wherein the alignment light detects the alignment marks according to the difference in reflection indexes and refraction indexes between the metal layer and the first dielectric layer.

13. The alignment method of claim 12, wherein a method for removing the metal layer outside the alignment trenches and the contact holes comprises chemical mechanical polishing.

14. The alignment method of claim 12, wherein widths of the alignment trenches are less than 0.75 micrometer.

15. The alignment method of claim 12, wherein a material of the first dielectric layer comprises silicon oxide.

16. The alignment method of claim 12, wherein a material of the metal layer comprises tungsten.

17. The alignment method of claim 12, wherein a thickness of the metal layer is larger than 400 nanometers.

18. The alignment method of claim 12, wherein a material of the mask layer comprises amorphous carbon.
